(19) United States
(12) Patent Application Publication
(10) Pub. No.: US 2022/0009781 A1
(43) Pub. Date: Jan. 13, 2022

(54) ONE-STEP GROWTH OF REDUCED GRAPHENE OXIDE ON ARBITRARY SUBSTRATES

(71) Applicant: KING ABDULLAH UNIVERSITY OF SCIENCE AND TECHNOLOGY, Thuwal (SA)

(72) Inventors: Mingguang CHEN, Thuwal (SA); Xixiang ZHANG, Thuwal (SA)

(21) Appl. No.: 17/295,170

(22) PCT Filed: Oct. 16, 2019
(86) PCT No.: PCT/IB2019/058830

§ 371 Date: May 19, 2021

Related U.S. Application Data
(60) Provisional application No. 62/775,430, filed on Dec. 5, 2018.
(60) Provisional application No. 62/782,680, filed on Dec. 20, 2018.

(51) Int. Cl. C01B 32/198; C01B 32/186; G01J 1/44; G01N 27/12; H01L 29/24; H01L 21/02

(52) U.S. Cl. CPC C01B 32/198; C01B 32/186; G01J 1/44; G01N 27/121; G01N 27/125; G01J 2001/4473; H01L 21/02565; H01L 21/0262; C01B 2204/04; C01B 2204/22; H01L 29/24

(57) ABSTRACT

A method for forming a cellulose acetate based reduced graphene oxide (CA-rGO) layer includes selecting a substrate; spin-coating a cellulose acetate dispersion on the substrate to obtain a cellulose acetate layer; and applying a given temperature profile to the cellulose acetate layer to transform it into the CA-rGO layer.

### CROSS-REFERENCE TO RELATED APPLICATIONS

This application claims priority to U.S. Provisional Patent Application No. 62/775,430, filed on Dec. 5, 2018, entitled “ONE-STEP GROWTH OF REDUCED GRAPHENE OXIDE ON ARBITRARY SUBSTRATES,” and U.S. Provisional Patent Application No. 62/782,680, filed on Dec. 20, 2018, entitled “ONE-STEP GROWTH OF REDUCED GRAPHENE OXIDE ON ARBITRARY SUBSTRATES,” the disclosures of which are incorporated herein by reference in their entirety.

### BACKGROUND

### Technical Field

Embodiments of the subject matter disclosed herein generally relate to a method for obtaining reduced graphene oxide (rGO), and more specifically, to techniques and processes that utilize cellulose acetate as a precursor to produce (a) uniform ultrathin rGO films on various substrates and/or (b) free-standing rGO powders.

### Discussion of the Background

Reduced graphene oxide (rGO) has attracted a great deal of attention from researchers due to its anticipated applications in transparent and flexible electronics, supercapacitors, batteries, sensors, photodetectors, electromagnetic shielding, etc. The rGO possesses higher in-plane electrical conductivity than graphene oxide (GO) and contains more active sites (e.g., hydroxyl groups and defects) for chemical functionalization and catalysis than pristine graphene.

Currently, modified Hummers' methods are the most popular way to prepare GO and its derivatives, such as rGO. An exemplary modified Hummers' method is briefly discussed with regard to FIG. 1. In step 100, a given amount of graphite is provided. The graphite is oxidized and intercalated in step 102, using a mixture of potassium permanganate (KMnO₄), NaNO₃, and concentrated H₂SO₄. These agents may be highly toxic and damaging for the environment and the operators manipulating them. The product obtained in step 102 is purified in step 104 to obtain the GO. Then, in step 106 an aqueous dispersion of the obtained GO is treated with reducing agents, such as a solution of hydrazine and ammonia, to partially restore the graphitic sp² carbon and to obtain the rGO. Note that the term “dispersion” is used herein to mean a system in which discrete particles of a first material are dispersed in a continuous phase of a second material, which is different from the first material. The two phases of the first and second materials may be the same or different states of matter. A dispersion is different from a solution, because in a solution the dissolved molecules do not form a separate phase from the solute. Finally, the rGO dispersions from step 106 are transferred in step 108 onto a target substrate, typically via spray or filtration for thin-film applications.

Due to the strong oxidizers and various reducing agents involved in these processes, it is difficult to control the size, roughness, and thickness of the end rGO product. Further, all these agents and catalysts are damaging to the environment and the operator of the method.

Thus, there is a need for a method of obtaining rGO in a way that does not involve dangerous chemicals, does not negatively impact the health of the person making the rGO, allows for a facile way of growing ultrathin rGO films on arbitrary substrates, and/or is capable of making free-standing rGO powders.

### SUMMARY

According to an embodiment, there is a method for forming a cellulose acetate based reduced graphene oxide (CA-rGO) layer. The method includes selecting a substrate, spin-coating a cellulose acetate dispersion on the substrate to obtain a cellulose acetate layer, and applying a given temperature profile to the cellulose acetate layer to transform it into the CA-rGO layer.

According to another embodiment, there is a sensor for measuring a physical parameter. The sensor includes a substrate, plural electrodes formed on the substrate, and a cellulose acetate derived reduced graphene oxide (CA-rGO) layer formed over the plural electrodes. The CA-rGO layer and the plural electrodes are treated by chemical vapor deposition at a temperature of at least 600° C.

According to still another embodiment, there is a method for forming a cellulose acetate based reduced graphene oxide (CA-rGO) device. The method includes a step of selecting a substrate, a step of forming plural electrodes on the substrate, a step of depositing a cellulose acetate dispersion on the plural electrodes to obtain a cellulose acetate layer, a step of placing the substrate and the cellulose acetate layer in a chemical vapor deposition system, and a step of applying a given temperature profile to the cellulose acetate layer to transform it into the CA-rGO layer.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a flowchart of a method for forming a reduced graphene oxide structure;

FIG. 2 is a flowchart of a method for forming a novel cellulose acetate based reduced graphene oxide thin film layer;

FIG. 3 shows a chemical vapor deposition system for forming the novel cellulose acetate based reduced graphene oxide thin films and powders;

FIG. 4 shows the chemical structure of the cellulose acetate;

FIG. 5 illustrates a thermal profile that is applied to form the novel cellulose acetate based reduced graphene oxide layer;

FIG. 6 illustrates the chemical structure of the novel cellulose acetate based reduced graphene oxide layer;

FIG. 7 illustrates a transistor formed with the novel cellulose acetate based reduced graphene oxide layer;

FIG. 8A shows the current-voltage characteristic of the transistor and FIG. 8B shows the profile of the transistor;

FIG. 9A shows a sensor that uses the novel cellulose acetate based reduced graphene oxide layer, FIG. 9B shows a setup for measuring a light intensity with the novel cellulose acetate based reduced graphene oxide layer, and FIG. 9C shows the results of that measurement;

FIG. 10A illustrates a setup for measuring the humidity with a sensor that includes the novel cellulose acetate based reduced graphene oxide layer, and FIG. 10B illustrates the measured response of the sensor and the associated humidity;

FIGS. 11A to 11E illustrate various characteristics of the novel cellulose acetate based reduced graphene oxide layer; and

FIG. 12 is a flowchart of a method for making a sensor using the novel cellulose acetate based reduced graphene oxide layer.

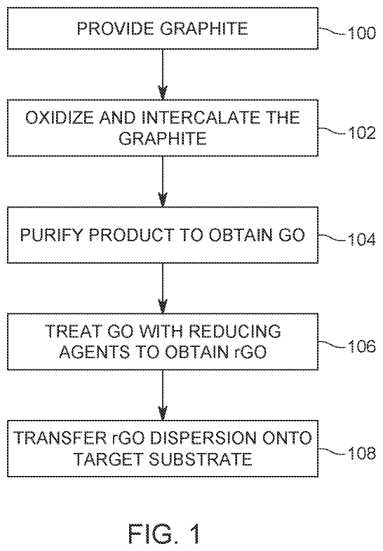

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a reduced graphene oxide sensor that may be used as a photosensor. However, the embodiments discussed herein are not limited to using the rGO material into a photosensor, as the rGO may be used for other purposes or in other electronic devices as a transistor, biosensors, batteries, displays, electromagnetic shields etc.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

The annual global production of cellulose acetate materials (note that cellulose reacts with acetic anhydride to form the cellulose acetate), such as thermoplastics, reached 800,000 tons in 2008, and many of these products are not recycled. According to an embodiment, a route to convert this cellulose acetate refuse into valuable rGO material, that may be used as a basis for manufacturing sensors, photodetectors, and electromagnetic shielding materials is disclosed. In this embodiment, a one-step growth process is introduced that utilizes cellulose acetate as a precursor to produce uniform ultrathin rGO films on various substrates and/or free-standing rGO powders. Systematic spectroscopic and microscopic studies on the resulting rGO were performed and their results, some of which are discussed later, prove the capability of the newly produced cellulose acetate derived rGO, called herein CA-rGO. Prototypes of electronic and optoelectronic devices, such as field effect transistors (FETs), photodetectors, and humidity sensors, were fabricated based on the CA-rGO material and their tests (some of which are also discussed later), demonstrate the potential applications of the novel CA-rGO materials across a wide range of fields.

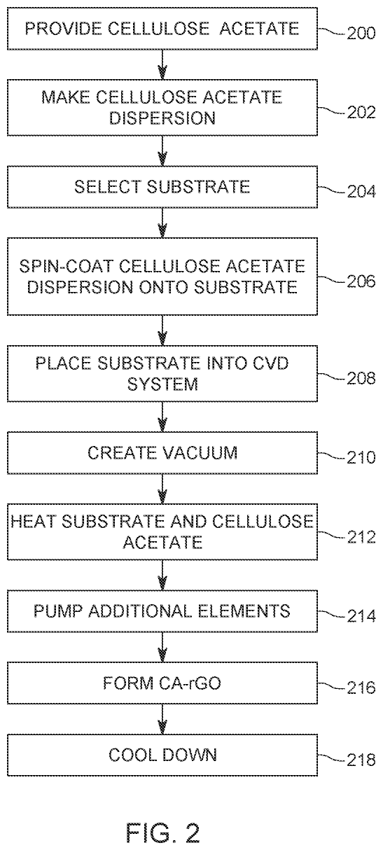

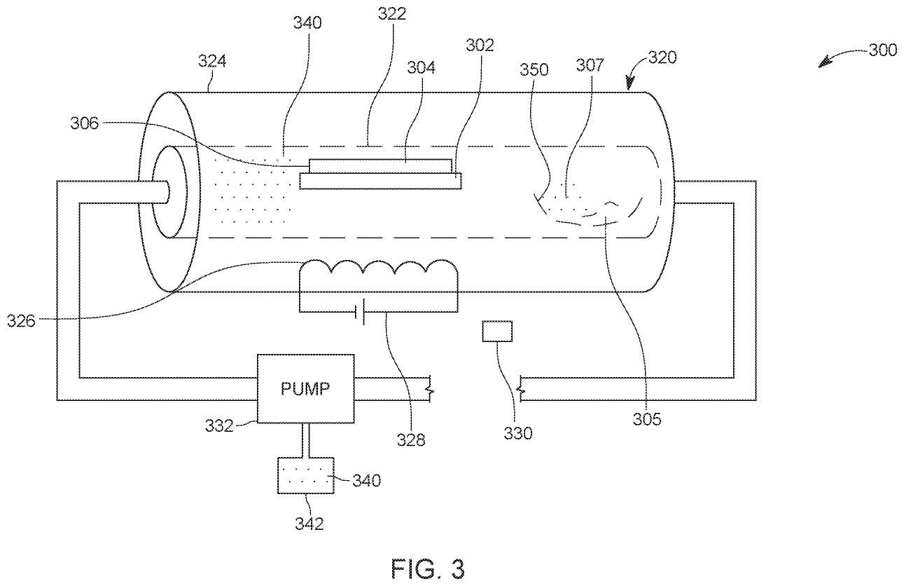

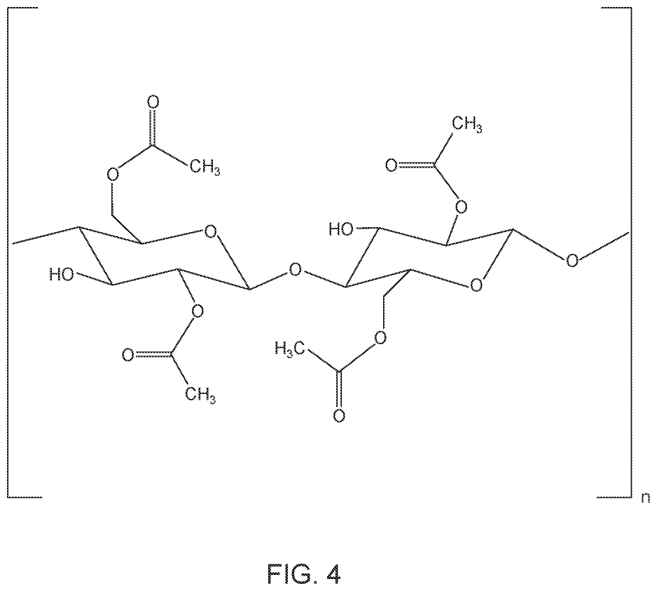

A method for obtaining CA-rGO is now discussed with regard to FIGS. 2 and 3. FIG. 2 is a flowchart illustrating the method and FIG. 3 shows the apparatus for obtaining the CA-rGO material. In step 200, cellulose acetate is provided and in step 202, the cellulose acetate is mixed with acetone to obtain cellulose acetate dispersion in acetone. A chemical composition of the cellulose acetate dispersion in acetone is shown in FIG. 4. In step 204, a substrate 302 is selected on which to form the CA-rGO is selected. The substrate may be made of any material, for example, glass, ceramic, polymer, metallic, etc. In step 206, the cellulose acetate dispersion in acetone is spin-coated on the substrate to obtain a layer 304, as shown in FIG. 3. For example, in one application, the substrate may be spinned at 5,000 rpm for about 60s. Other values may be used. A thickness t of the layer 304 may be controlled to obtain a desired value. In one embodiment, the thickens t has a value of 1.00+/−0.30 μm. In one application, the thickness t is less than 2 μm. In step 208, the substrate 302 and cellulose acetate layer 304 are placed inside a chemical vapor deposition (CVD) system 320 (a modified continuous stirred-tank reactor method (CSTR) may also be used). The CVD system 320 may have a quartz tube 322 located inside of a housing 324 of the CVD system 320. A heating element 326 is provided inside the housing 324, next to the quartz tube 322, for heating the inside of the quartz tube. The heating element 326 may be a resistive element, an inductive element, a capacitive element, etc. The heating element is connected to a power source 328. Although the process described herein can work without any catalyst, in one application it is possible to provide Cu or Ni foils and powders, for example, inside the quartz tube, during the heating process as catalysts, to improve the grain sizes of the obtained CA-rGO.

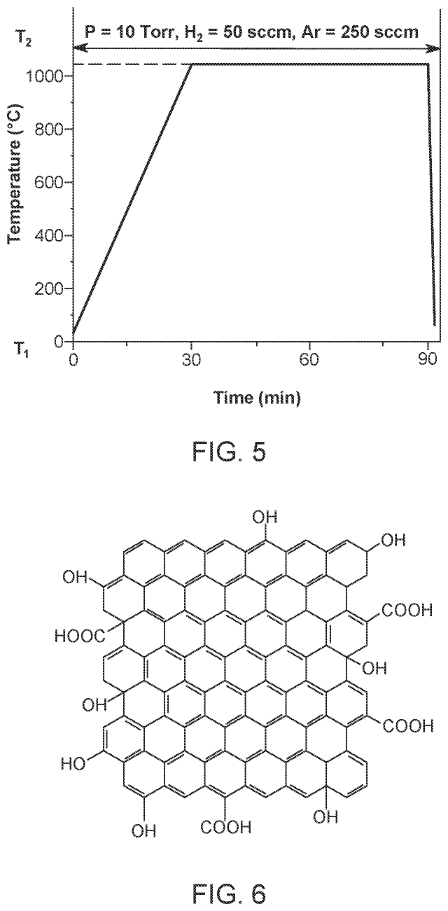

In step 210, vacuum is established inside the quartz tube 322, for example, with a vacuum pump 332, which is connected through corresponding piping to the CVD system 320. In one application, the vacuum may be about 1 mtorr (i.e., high vacuum). In step 212, the substrate 302 and coating layer 304 are heated to a desired temperature. The heating is controlled by a controller 330, which may be implemented as an integrated circuit, or a computing device. In one application, the heat profile applied to the substrate 302 and the cellulose acetate dispersion layer 304 is shown in FIG. 5. Note that the temperature starts from an initial, low temperature T1 (for example, room temperature), increases with a constant gradient to a high temperature T2 (for example, 1040° C.) over a first given time dt₁ (for example, between 10 and 30 minutes), and then the high temperature T2 is maintained constant fora second given time dt₂ (for example, between 30 and 100 minutes).

At the beginning and during the heating step 212 of the substrate 302 and layer 304, in step 214, one or more elements 340 are introduced into the quartz tube 322, for example, by pump 332. At the same time, it is possible to pump away byproducts of the reactions taken place inside the system. The one or more elements 340 are stored in one or more tanks 342 (only one tank is shown in the figure for simplicity, but it is possible to have as many tanks as the number of pumped elements), which are connected to the pump 332. In one application, two elements are pumped into the quartz tube 322, H₂ and Ar. The pressure at which these two elements is pumped may be about 10 torr. In one implementation, the H₂ molecules are pumped at a rate of 50 standard cubic centimeters per minute (sccm) while the Ar atoms are pumped at a rate of 250 sccm. However, it is possible to use any pressure between 1 and 20 Torr, and the pumped H₂ may be between 0 and 30% of total elements pumped inside the CVD system. More than two elements may be pumped at the same time inside the CVD system. While the pressure and the rates of the pumped elements are maintained constant, the temperature profile shown in FIG. 4 (or another temperature profile) is applied in step 212.

The combination of high temperature, added elements, and the cellulose acetate dispersion spinned on the substrate, transform layer 304 into CA-rGO layer 306 in step 216. In step 218, after the prescribed time of high temperature T2, the quartz tube 322 is quickly cooled down to room temperature by an air flow.

The dispersion of cellulose acetate exhibits a Tyndall effect under a beam of red laser (635 nm), suggesting the fine particles of cellulose acetate polymer were well dispersed in the acetone. The thickness of the cellulose acetate layer 304 can be precisely controlled by the concentration of cellulose acetate dispersion and the spin parameters (time, speed, acceleration, etc.). The CA-rGO material can be grown in the form of films 306, as shown in FIG. 3. However, the CA-rGO material can also be grown as a powder, for example, if instead of spin-coating the layer 304 on the substrate 302, the cellulose acetate powders are simply placed in a vessel 350, and treated under the same temperature and pressure conditions as the layer 304, to obtain CA-rGO powder material 307.

The obtained CA-rGO layer 306 or powder 307 has the chemical structure shown in FIG. 6. It is noted the presence of the functionalized groups OH and COOH, which are beneficial for various reasons, as discussed later. For the process discussed with regard to FIG. 2, no catalysts are necessary; therefore, CA-rGO can be grown on arbitrary substrates, which is not the case for the traditional methods. Thus, the dangerous agents used in the traditional methods are avoided with the present method.

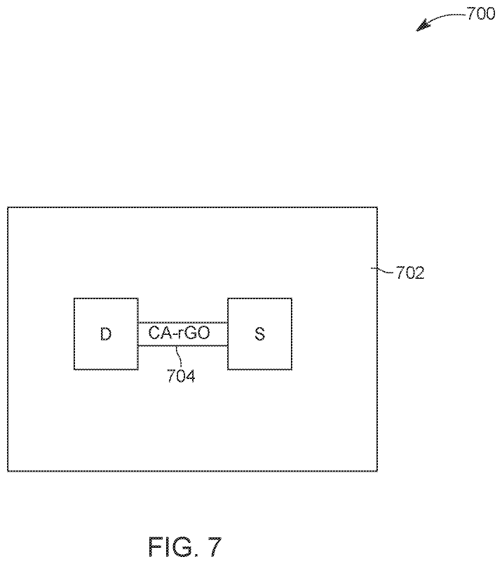

The method discussed with regard to FIG. 2 may be modified to fabricate a transistor 700, which is illustrated in FIG. 7. An appropriate substrate 702 (e.g., SiO₂/Si) is selected in step 204, and after the cellulose acetate dispersion layer 704 is deposited in step 206 over the substrate 702, a step of patterning the layer 704 is implemented to obtain the desired shapes for the future drain D, source S, and gate G. During the step 214, it is possible to allow additional elements to enter inside the quartz tube 322, to dope the CA-rGO regions directly, during the grow process, with transition metals, such as Ag and Cu, or to introduce antibacterial properties relevant for applications in wastewater treatment. For example, a mix of CuCl₂ reagents may be added to the acetone dispersion of cellulose acetate and deposited in step 206 over the substrate 702, and then treated under the same temperature and pressure conditions as the layer 304/704. The H₂ gas introduced into the chamber will reduce the Cu²⁺ to Cu atoms, which are adsorbed on the surface of the rGO or bond with dangling bonds from the rGO or inserted between two graphitic layers of the rGO and form organometallic bonds with them.

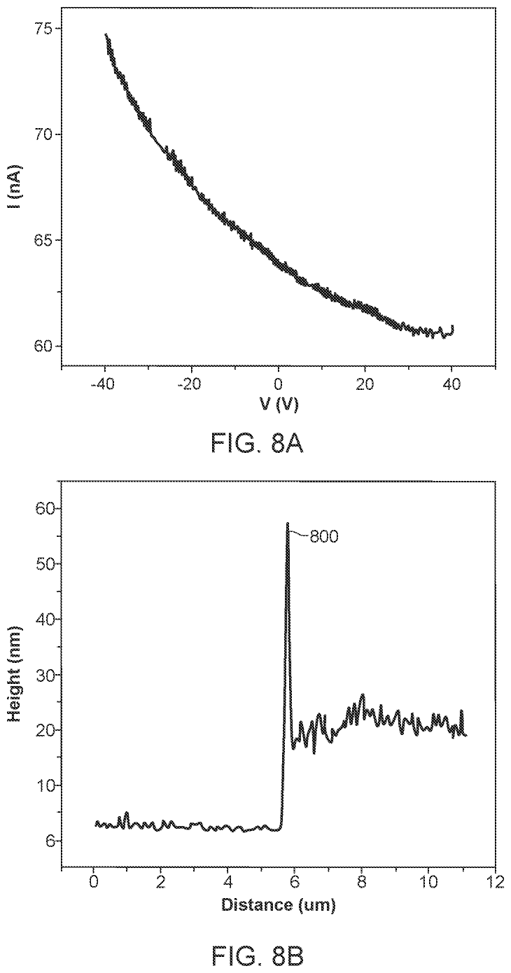

In this way, a CA-rGO film-based FET device 700 may be fabricated on a 300 nm SiO₂/Si substrate. For this process, no catalysts are necessary. Measurements of the FET transistor 700 transfer characteristics (current versus voltage) using the CA-rGO material (see FIG. 8A) show a p-type transistor, which is due to the functionalized hydroxyl groups in CA-rGO and the dopants from air. Note that the resistance of the transistor 700 at 0 voltage was calculated to be 15.7 MΩ, which is attributed to the nanoscale dimensions and a poor interconnection among the CA-rGO nanoplatelets. The junction conductance of the CA-rGO transistor may be improved by organometallic chemistry and single-walled carbon nanotubes.

An atomic force microscopy (AFM) height profile (see FIG. 8B) was collected from the FET device and it shows that the average thickness of the CA-rGO film is less than 40 nm, e.g., about 20 nm, which gives a large surface area of these films and facilities the application of CA-rGO as a competitive sensor material. The abrupt peak 800 around 6 μm is likely due to the turnover of the edges of the film device during the photolithography process.

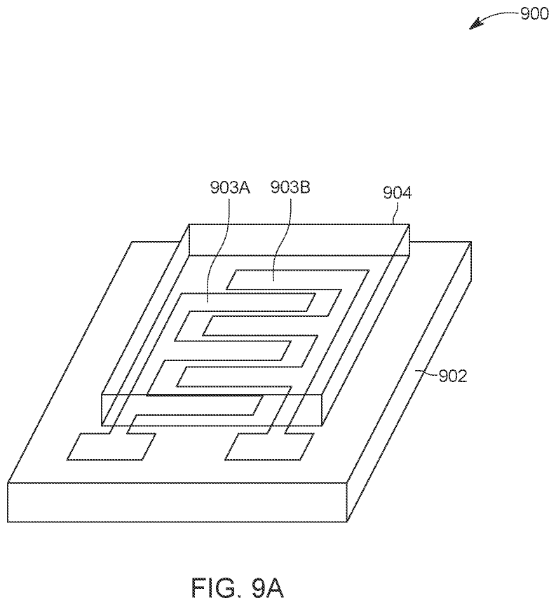

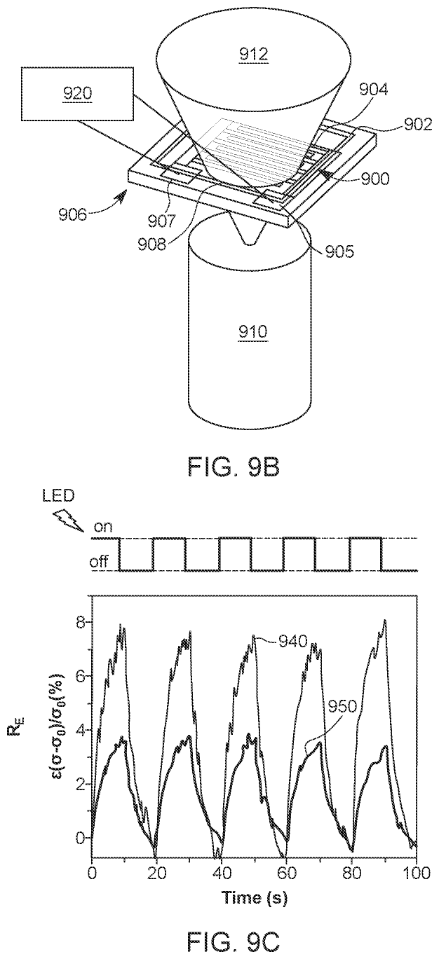

The CA-rGO material may also be used for various sensors, specifically, photodetectors and humidity sensors. FIG. 9A shows such sensor 900 formed on a quartz substrate 902. The sensor 900 includes a first plurality of electrodes 903A, which are interdigitated with a second plurality of electrodes 903B. A layer of CA-rGO 904 was formed on top of the plural electrodes 903A and 903B. Electrode pads 905 and 907 are connected to the plurality of electrodes 903A and 903B, respectively. The entire sensor 900 is placed on a sample holder 906, as shown in FIG. 9B for testing purposes. The sample holder 906 has a hole 908 (e.g., having a diameter of about 5.6 mm) through which light 912, from a light source 910 (e.g., LED light), is passing to interact with the sensor 900, which is used now as a photodetector. A probe station 920 (e.g., an oscilloscope) is connected at the terminals 905 and 907 of the photodetector 900, for measuring the voltage detected by the sensor.

FIG. 9C shows a first curve 940 that corresponds to the effective photoresponse R_{E} of the photodetector 900 for white light and a second curve 950 for UVA light (365 nm wavelength). The photoresponse R_{E} is calculated as follows:

$$ɛ = \frac{Device Area}{Illuminated area} = \frac{9 \times 9}{25 / 2} = 6.48 \\ R = \frac{σ - {σ}_{0}}{σ} , \\ and$$

$${R}_{E} = R \cdot ɛ ,$$

where ε is the effective photoresponse coefficient, σ is the electrical conductivity of the CA-rGO thin film, R is the measured photoresponse, and R_{E} is the effective photoresponse.

In this embodiment, 90 interdigitated Ti/Au (10/100 nm) electrodes 903A and 903B, with a 40 μm electrode width, 40 μm electrode separation, and 8.8 mm electrode length were prepared on the quartz substrate by nanofabrication. The resulting channel width to length ratio for the entire sensor is 19,800. Then photolithography was used to define the cellulose acetate square (9 mm×9 mm) 904 on top of the interdigitated electrodes, and the cellulose acetate was transformed into CA-rGO under the same conditions described with regard to FIG. 2, except that the reaction temperature was 850° C. instead of 1040° C. in order to protect the electrodes 903A and 903B. The reaction temperature may be as low as 600° C. for forming the CA-rGO layer. The measurements of the CA-rGO photodetector were taken using a Keysight B2912A sourcemeter as the source probe 920 and multiple LEDs 910 with different wavelengths were used. The LEDs were supplied with a Tektronix AFG3252 function generator for photoresponse measurements. The area of the hole for illumination was 25 mm².

The CA-rGO photodetectors responded quickly to both UV and visible lights at a frequency of 0.05 Hz, in fact faster than most rGO photodetectors and single-walled carbon nanotube/ZnO heterostructure based photodetectors reported in the literature. It is believed that the performance of the photodetector 900 could be further improved by chemical functionalization, band-gap engineering, or by combining other 2D materials to create heterojunctions.

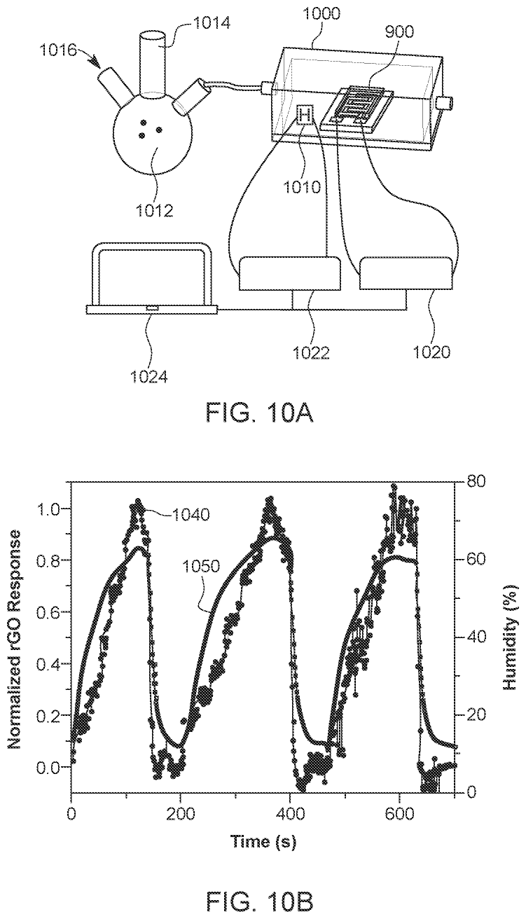

The sensor 900 was also used as a humidity sensor as now discussed. The photodetector 900 was placed inside a closed chamber 1000, in which a reference humidity sensor 1010 was also placed. The atmosphere of the closed chamber 1000 is strictly controlled and its humidity may be varied by pumping more or less water vapors 1012 from a container 1014. Other gases 1016 may also be mixed with the water vapors 1012 for testing the sensitivity of the sensor 900, when acting as a humidity sensor. A voltage source 1020 was connected to the terminals of the sensor 900 for measuring its voltage, and the measured signals were passed to a computing device 1024, for calculating the humidity. Another source 1022 was connected to the humidity sensor 1010 for measuring its voltage and this info was also passed to the computing device 1024. By running a dedicated software program, e.g., Matlab, it was possible to calculate the humidity associated with each of the sensors 900 and 1010. The values of the humidity are plotted in FIG. 10B, where curve 1040 shows the normalized response of the CA-rGO sensor 900 and curve 1050 shows the corresponding humidity associated with the normalized response. The sensor 900 had a 20 nm thick layer of CA-rGO.

The 2D nature, abundant hydroxyl groups, and sufficient chemically active sites of the CA-rGO layer 306 or 904 lead to promising sensing devices. The CA-rGO systems discussed herein have shown the capability of measuring a humidity of a modulated humid flow, with a humidity varying from 16%-62% (see FIG. 10B). This was the limit of the humidity inside the chamber 1000. The response was normalized in regard to the conductance G measured at low humidity (G_{L}) and at high humidity (G_{H}): G_{N}=(G-G_{L})/(G_{H}-G_{L}).

The response time of the CA-rGO layer was about 100 s and the recovery time was about 8 s, which is comparable to the previously reported rGO humidity sensors. It is believed that by further optimization of the film thickness, manufacturing setup, dopants (N, F), and functionalized groups, ultrafast CA-rGO sensors can be obtained in the future.

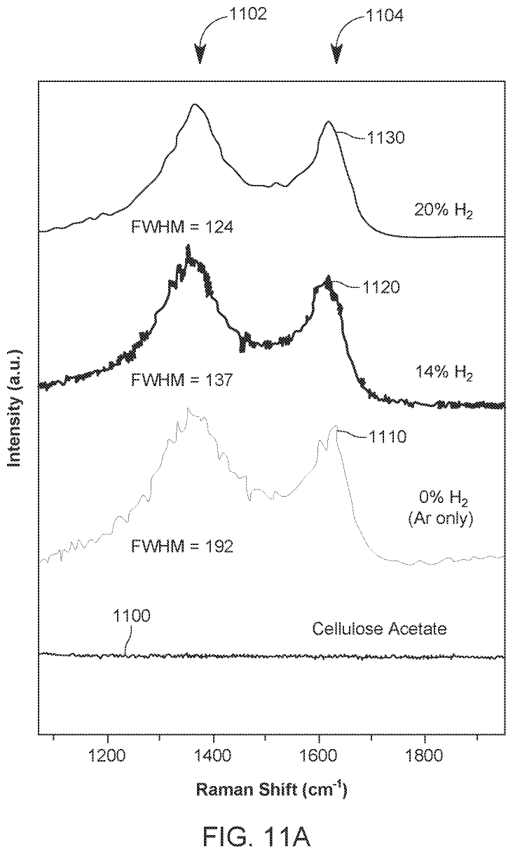

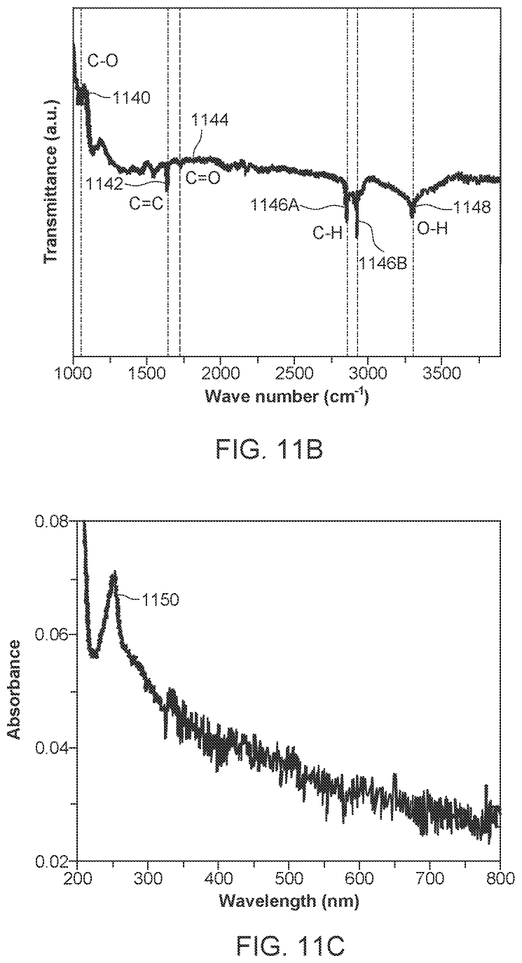

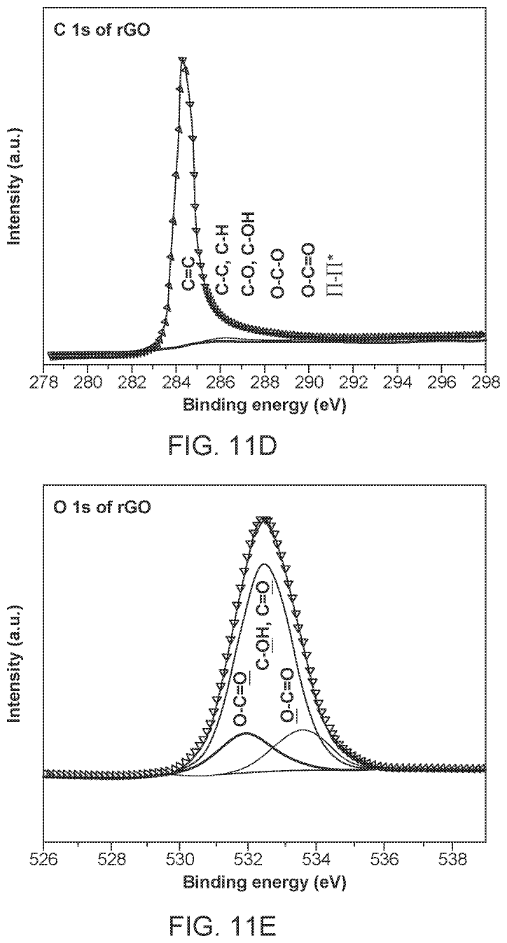

The CA-rGO based devices discussed above were investigated with various methods, for example, spectroscopy analysis. Raman spectroscopy is a very sensitive and nondestructive tool for characterizing carbon nanomaterials, especially graphene and its derivatives. FIG. 11A compares the Raman spectra of a CA-rGO film with the precursor, cellulose acetate film, before and after chemical reactions under different conditions, curve 1110 was obtained for no H₂ being pumped into the CVD system in FIG. 3, curve 1120 was obtained for 14% H₂ being pumped during the fabrication process of the CA-rGO layer 306 in the CVD system 300, and curve 1130 was obtained for 20% H₂ being pumped during the fabrication process of the CA-rGO layer 306 in the CVD system 300.

Before the reaction in the CVD system 300, the pure cellulose acetate (described by curve 1100) shows no obvious peak in the Raman spectrum range 1050-1950 cm⁻¹. However, after a chemical reaction at 1040° C. for 1 hour, the CA-rGO layer was obtained as evidenced by the high D-peak 1102 at ˜1367 cm⁻¹, and the prominent G-peak 1104 at ˜1619 cm⁻¹. The G mode of graphitic materials is ascribed to E_{2g} symmetry, and unlike the D mode, the activation of the G mode does not require defects. The shift of the G-peak for curve 1120 in the CA-rGO layer (1619 cm⁻¹) compared to pristine CVD graphene (1584 cm⁻¹) was attributed to the presence of nanocrystalline graphene in the CA-rGO samples because the merger of the D′ peak with the G peak in small grain graphene can result in the upshift of the G peak. It was also observed that the full width at half maximum (FWHM) of the D peak increased as the H₂ percentage decreased. The D peak is related to the A_{1g} breathing mode, and is activated by disorders in the graphene. The shift of the D peak in curve 1120 in the CA-rGO layer compared to pristine graphene may come from the small-size graphene domains in CA-rGO.

The I_{D}/I_{G} ratio is widely used to characterize graphitization in carbon materials. In general, the better the graphitization, the smaller the I_{D}/I_{G} ratio. A higher percentage of H₂ gas, restored the sp² carbon to a large extent and, therefore, resulted in a smaller D peak as shown in FIG. 11A. It is also noted that the height of the D peak was higher than the G peak in the CA-rGO film, consistent with previously reported Raman spectra of rGO produced by modified Hummer methods. In intensively oxidized graphene oxide, on the other hand, the literature reports that the height of D peak is lower than the G peak.

To appreciate the functional groups in the CA-rGO layer 306, mid-infrared spectroscopy was performed on a 20 nm thick CA-rGO layer formed on a quartz substrate. Normally, rGO samples are graphene functionalized with oxygen-containing groups found at the edges or in the defects of the basal plane. FIG. 11B illustrates the presence of a C—O (phenolic) stretching vibration peak 1140 at 1055 cm⁻¹, a C═C (sp² hybridized carbon) skeletal vibration peak 1142 at 1631 cm⁻¹, a C═O stretching vibration peak 1144 at 1730 cm⁻¹, C—H stretching vibration peaks 1146A and 1146B at 2848 cm⁻¹ and 2917 cm⁻¹, and an O—H vibration peak 1148 at 3297 cm⁻¹. The pronounced C═C peak 1142 and weak C—O and C═O stretching vibrations indicates the graphene-like electronic structure of these samples, distinguishing them as rGO and not GO. Interestingly, prominent peaks corresponding to C—H vibrations 1146A and 1146B are observed in the CA-rGO layers, suggesting that some of their edges terminated with a hydrogen. A broad and evident peak related to a hydroxyl group is rare in rGOs derived from GO using modified Hummer methods. The enrichment of these 0-H groups suggests possible applications of the CA-rGO material in humidity sensors, because the CA-rGO material contains higher in-plane conductivity than GO and more 0-H groups than either traditional rGOs or graphene.

The UV-vis spectra of the 20 nm thick CA-rGO layer showed a weak absorbance of wavelengths within the 200-800 nm range due to the ultrathin thickness (see FIG. 110), with a peak 1150 at about 250 nm, which corresponds to the π→π* transitions. Since oxygen-containing covalently functionalized chemical groups exist in the CA-rGO layer, it is believed that the shift of this peak in the CA-rGO film compared to that of pure graphene nanoplatelets (˜270 nm) is due to its incomplete graphene-like electronic structure. The absorbance coefficient at 660 nm is calculated to be 1.5×10⁴ cm⁻¹.

The elemental composition of the CA-rGO layer was further analyzed by X-ray photoelectron spectroscopy (XPS). Only carbon and oxygen elements were detected in both samples, suggesting high purity of the CA-rGO layer. The O/C ratio in the cellulose acetate was calculated to be 0.53, which reduced to 0.01 after graphitization, as shown in the CA-rGO survey spectra, indicating that the oxygen content drastically decreased after the reaction. The C 1s core level from cellulose acetate (not shown) was fitted using four components, located at 285.0 eV, 286.4 eV, 287.5 eV, and 288.9 eV, corresponding to the C—C/C—H (sp³), C—O/C—OH, O—C—O, and O—C═O bonds, respectively. The O 1s core level (not shown) from cellulose acetate was fitted using three components, located at 531.9 eV, 532.7 eV, and 533.4 eV, corresponding to the O—C═O, O—C—O/C—OH, and O—C═O bonds, respectively. The XPS intensity ratio of the O—C═O peak to the O—C—O peak was about 2:1, consistent with the chemical structure shown in FIG. 4. FIG. 11D illustrates the high resolution XPS spectra of the C 1s core level from the CA-rGO layer. The C 1s core level was fitted using six components, located at 284.4 eV, 285.0 eV, 286.4 eV, 288.0 eV, 289.2 eV, and 290.6 eV, corresponding to the C═C (sp²), C—C/C—H (sp³), C—O/C—OH, C═O, and O—C═O bonds, and to the π-π* shake-up satellite-structure characteristic of a conjugated system, respectively. The C 1s spectrum is dominantly from graphitic carbon, confirming that the sp³ carbon in cellulose acetate has been turned into sp² carbon in CA-rGO after the reaction. The O 1s core level in FIG. 11E was fitted using three components, located at 532.0 eV, 532.6 eV, and 533.7 eV, corresponding to the O—C═O, C═O/C—OH, and O—C═O bonds, respectively. The oxygen level in the CA-rGO material was estimated to be 1%, which is much lower than the regular graphene oxide. The XPS characterizations provide further evidence that the obtained CA-rGO layer is rGO in nature, instead of GO.

The microscopy analysis of the CA-rGO layer included AFM measurements for investigating the morphology of the used materials before and after the reaction in the CVD system 300. An AFM image of a spin-coated cellulose acetate film (similar to layer 304) with porous structures was estimated to have the average pore size (diameter) of about 140 nm, and a wall thickness between adjacent pores to be about 70 nm. After the reaction in the CVD system 300, randomly but uniformly distributed and interconnected CA-rGO nanoplatelets (˜50 nm in diameter) were observed. The CA-rGO thin film was first grown on Cu foils and then transferred to a TEM grid following a previously reported clean graphene-transfer method. The CA-rGO nanoplatelets were densely packed and interconnected with each other. Interestingly, in some areas, the separated CA-rGO islands were connected to each other by graphene-like thin films. Raman mapping of the D peak further proved that the interconnected areas had a lower D peak, indicating a graphene-like structure. The CA-rGO nanoplatelets were observed to be polycrystalline, with an approximate domain size of 10 nm×10 nm. The typical honeycomb-lattice structure of multilayer graphene with an AB stack between the adjacent layers has been observed. The C═C bond distance in the tested CA-rGO film was measured to be 0.152 nm, consistent with the literature values.

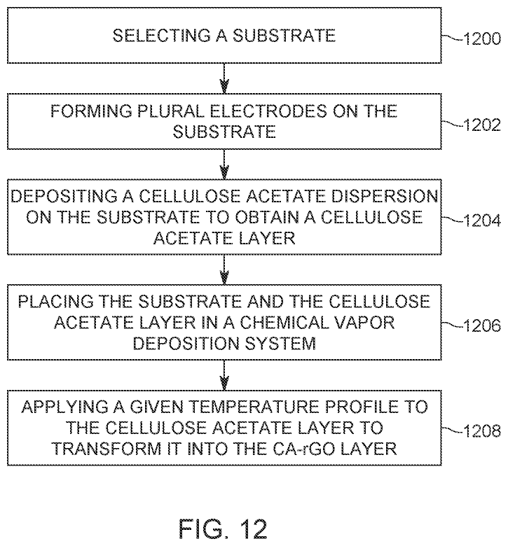

A method for forming a cellulose acetate based reduced graphene oxide (CA-rGO) device is now discussed with regard to FIG. 12. The method includes a step 1200 of selecting a substrate 302, which can be any substrate, a step of forming plural electrodes 903A, 903B on the substrate, a step 1202 of forming plural electrodes 903A and 903B on the substrate (in one application, the plural electrodes 903A are interdigitated with the plural electrodes 903B), a step 1204 of depositing a cellulose acetate dispersion on the plural electrodes 903A and 903B, to obtain a cellulose acetate layer 304, a step 1206 of placing the substrate 302 and the cellulose acetate layer 304 in a chemical vapor deposition system 300, and a step 1208 of applying a given temperature profile to the cellulose acetate layer 304 to transform it into the CA-rGO layer 306.

A thickness of the cellulose acetate layer is 2 μm or less and a thickness of the CA-rGO layer is 40 nm or less. In one application, the cellulose acetate dispersion is in acetone. The given temperature profile is applied in an isolated tube (the term “isolated” in understood herein to describe a tube that may have a continuous gas in and gas out, but the tube is isolated from the outside air) for chemical vapor deposition. A pressure inside the isolated tube may be less than 20 torr. The method may also include a step of introducing atoms of hydrogen in the insulated tube while applying the given temperature profile, and/or a step of introducing atoms of Ar in the insulated tube while applying the given temperature profile, and/or a step of introducing metallic atoms in the insulated tube for doping the CA-rGO layer. In one application, the method may include a step of forming a transistor that has the drain and/or source as the CA-rGO layer, and/or forming on the substrate plural electrodes; and forming the CA-rGO layer on top of the plural electrodes to obtain a sensor. The sensor is not limited to a humidity sensor or a photodetector.

The above discussed embodiments introduce a one-step growth method of CA-rGO films from cellulose acetate on arbitrary substrates, which is far simpler than the traditional processes for preparing rGO. The size of the obtain CA-rGO nanoplatelets that make up the layer and their extent of graphitization can be mediated by controlling the reaction temperature and the percentage of H₂ in the reductive gas mixture. The graphene-like in-plane crystalline structure of the novel CA-rGO thin film, along with its abundant chemically active sites (hydroxyl groups and defects) and large surface area, enable the fabrication of high-performance photodetectors and humidity sensors, among other devices.

This one-step growth method also allowed to dope the CA-rGO layer directly during the grow process, for example, with transition metals, such as Ag and Cu, and/or to introduce antibacterial properties relevant for applications in wastewater treatment.

The disclosed embodiments provide a method for generating CA-rGO layers that may be used in various electronic structures (e.g., photodetectors, humidity sensors, transistors). It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A method for forming a cellulose acetate based reduced graphene oxide (CA-rGO) layer, the method comprising:
selecting a substrate;
spin-coating a cellulose acetate dispersion on the substrate to obtain a cellulose acetate layer; and
applying a given temperature profile to the cellulose acetate layer to transform it into the CA-rGO layer.

2. The method of claim 1, wherein a thickness of the cellulose acetate layer is 2 μm or less.

3. The method of claim 1, wherein a thickness of the CA-rGO layer is 40 nm or less.

4. The method of claim 1, wherein the cellulose acetate dispersion is in acetone.

5. The method of claim 1, wherein the given temperature profile is applied in an insulated tube for chemical vapor deposition.

6. The method of claim 5, wherein a pressure inside the insulated tube is less than 20 torr.

7. The method of claim 5, further comprising:
introducing atoms of hydrogen in the insulated tube while applying the given temperature profile.

8. The method of claim 7, further comprising:
introducing atoms of Ar in the insulated tube while applying the given temperature profile.

9. The method of claim 8, further comprising:
introducing metallic atoms in the insulated tube for doping the CA-rGO layer.

10. The method of claim 9, further comprising:
forming a transistor that has a drain and/or source as the CA-rGO layer.

11. The method of claim 1, further comprising:
forming on the substrate plural electrodes; and
forming the CA-rGO layer on top of the plural electrodes to obtain a sensor.

12. The method of claim 11, wherein the sensor is a humidity sensor.

13. The method of claim 11, wherein the sensor is a photodetector.

14. A sensor for measuring a physical parameter, the sensor comprising:
a substrate;
plural electrodes formed on the substrate; and
a cellulose acetate derived reduced graphene oxide (CA-rGO) layer formed over the plural electrodes,
wherein the CA-rGO layer and the plural electrodes are treated by chemical vapor deposition at a temperature of at least 600° C.

15. The sensor of claim 14, wherein a thickness of the CA-rGO layer is 40 nm or less.

16. The sensor of claim 14, wherein the plural electrodes are interdigitated.

17. The sensor of claim 14, wherein the physical parameter is light intensity.

18. The sensor of claim 14, wherein the physical parameter is humidity.

19. A method for forming a cellulose acetate based reduced graphene oxide (CA-rGO) device, the method comprising:
selecting a substrate;
forming plural electrodes on the substrate;
depositing a cellulose acetate dispersion on the plural electrodes to obtain a cellulose acetate layer;
placing the substrate and the cellulose acetate layer in a chemical vapor deposition system; and
applying a given temperature profile to the cellulose acetate layer to transform it into the CA-rGO layer.

20. The method of claim 19, wherein a thickness of the CA-rGO layer is 40 nm or less, the cellulose acetate dispersion is in acetone, and atoms of hydrogen and Ar are introduced in the chemical vapor deposition system while the CA-rGO layer is formed.
